(19) United States
(12) Patent Application Publication
(10) Pub. No.: US 2023/0395729 A1
(43) Pub. Date: Dec. 7, 2023

(54) MEMORY DEVICES WITH GRADIENT-DOPED CONTROL GATE MATERIAL

(71) Applicant: Intel Corporation, Santa Clara, CA (US)

(72) Inventors: Arkajit Roy Barman, San Ramon, CA (US); Dimitrios Pavlopoulos, Glendale, CA (US); Dimitri Robert Kioussis, San Jose, CA (US); Srikant Jayanti, Fremont, CA (US); Jeremy Leroy Schroeder, Toledo, OH (US)

(73) Assignee: Intel Corporation, Santa Clara, CA (US)

(21) Appl. No.: 18/249,635

(22) PCT Filed: Dec. 10, 2020
(86) PCT No.: PCT/CN2020/135345

§ 371 Date: Apr. 19, 2023

(51) Int. Cl. H01L 29/788; H10B 41/27

(52) U.S. Cl. CPC H01L 29/7883; H10B 41/27

(57) ABSTRACT

Disclosed herein are memory devices with gradient-doped control gate material, as well as related methods and devices. In some embodiments, a memory device may include a first isolation material, a second isolation material, and a control gate material between the first isolation material and the second isolation material along an axis. The control gate material may include a dopant having a non-uniform concentration along the axis.

### BACKGROUND

Memory devices typically include a number of memory cells joined by control lines. Each cell may be able to store a single bit of information.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a side, cross-sectional view of a memory device including gradient-doped control gate material, in accordance with various embodiments.

FIGS. 1B and 10 are example doping profiles that may be used in a gradient-doped control gate material, in accordance with various embodiments.

FIGS. 2A-2G illustrate stages in an example process of manufacturing a memory device including gradient-doped control gate material.

FIG. 3 is a side, cross-section view of another memory device including gradient-doped control gate material, in accordance with various embodiments.

FIG. 4 is a top view of a wafer and dies that may include a memory device including gradient-doped control gate material, in accordance with any of the embodiments disclosed herein.

FIG. 5 is a side, cross-sectional view of an integrated circuit (IC) device that may include a memory device including gradient-doped control gate material, in accordance with any of the embodiments disclosed herein.

FIG. 6 is a side, cross-sectional view of an IC package that may include a memory device including gradient-doped control gate material, in accordance with any of the embodiments disclosed herein.

FIG. 7 is a side, cross-sectional view of an IC device assembly that may include a memory device including gradient-doped control gate material, in accordance with any of the embodiments disclosed herein.

FIG. 8 is a block diagram of an example electrical device that may include a memory device including gradient-doped control gate material, in accordance with any of the embodiments disclosed herein.

### DETAILED DESCRIPTION

Disclosed herein are memory devices with gradient-doped control gate material, as well as related methods and devices. In some embodiments, a memory device may include a first isolation material, a second isolation material, and a control gate material between the first isolation material and the second isolation material along an axis. The control gate material may include a dopant having a non-uniform concentration along the axis.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrases “A and/or B” and “A or B” mean (A), (B), or (A and B). For the purposes of the present disclosure, the phrases “A, B, and/or C” and “A, B, or C” mean (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

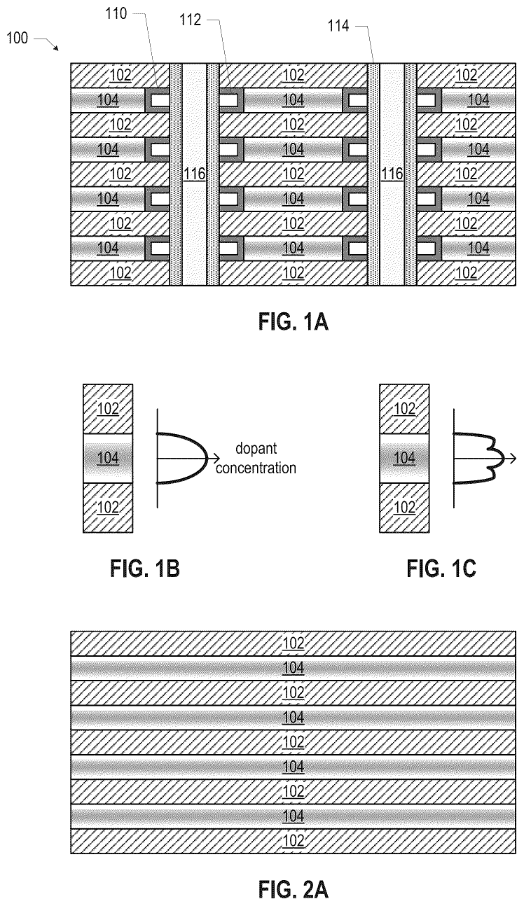

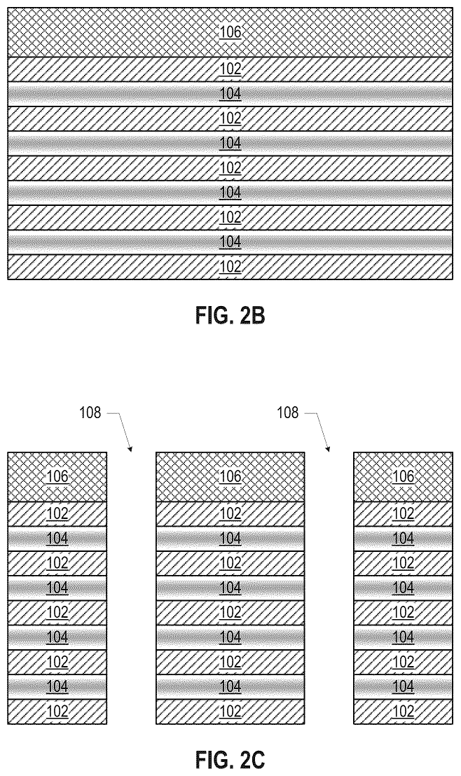

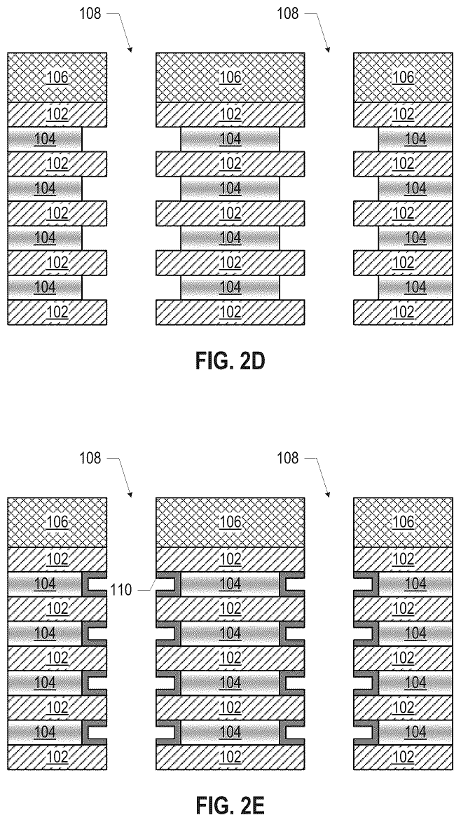

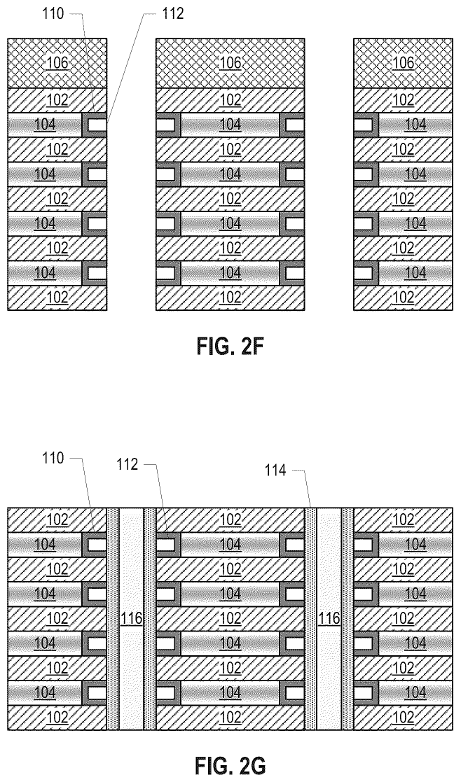

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. When used to describe a range of dimensions, the phrase “between X and Y” represents a range that includes X and Y. For convenience, the phrase “FIG. 1” may be used to refer to the collection of drawings of FIGS. 1A-1C and the phrase “FIG. 2” may be used to refer to the collection of drawings of FIGS. 2A-2G.

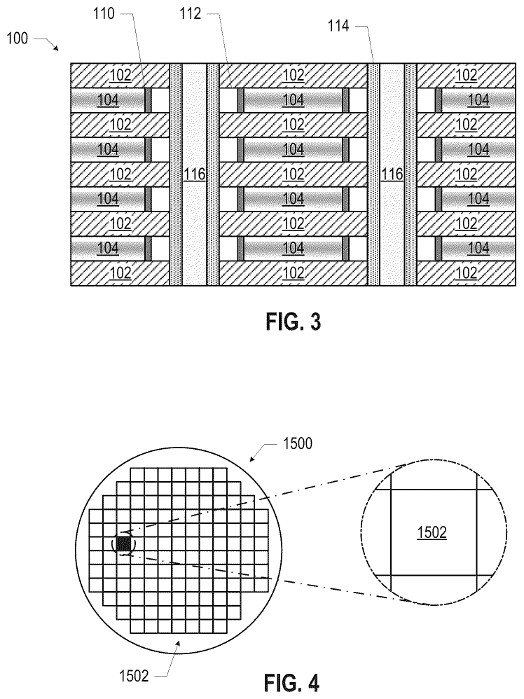

FIG. 1A is a side, cross-sectional view of a memory device 100 including gradient-doped control gate material 104, in accordance with various embodiments. The memory device 100 may be a three-dimensional (3D) NAND memory device, for example. The memory device 100 may include a stack of gradient-doped control gate material 104 alternating with isolation material 102. The isolation material 102 may include any suitable electrically insulating material, such as an electrically insulating oxide or nitride (e.g., silicon oxide or silicon nitride). The gradient-doped control gate material 104 may be laterally recessed with respect to the isolation material 102, and dielectric material 110 and floating gate material 112 may be disposed in the recesses. The dielectric material 110 may be between the floating gate material 112 and the gradient-doped control gate material 104; in the embodiment of FIG. 1A, the dielectric material 110 may have a C-shaped cross-section, while in other embodiments, the dielectric material 110 may not have a C-shaped cross-section (e.g., as discussed below with reference to FIG. 3). The dielectric material 110 may include any suitable dielectric material, such as an oxide or nitride (e.g., silicon oxide or silicon nitride), and the floating gate material 112 may include any suitable material (e.g., polysilicon). In some embodiments, the floating gate material 112 may have a non-uniform doping profile along the axis (e.g., concave up, concave down, ramping up, ramping down, a combination, etc.). In some embodiments, the dielectric material 110 may be an inter-poly dielectric (IPD). A cell pillar material 116 may be spaced apart from the floating gate material 112 by a tunnel dielectric material 114 (which, in some embodiments, may extend continuously along lateral faces of the isolation material 102 and the floating gate material 112, as shown). The tunnel dielectric material 114 may include any suitable dielectric material, such as an oxide or nitride (e.g., silicon oxide or silicon nitride), and the cell pillar material 116 may include any suitable material (e.g., polysilicon or silicon oxide).

The dimensions of the elements of the memory device 100 may take any suitable values. In some embodiments, the isolation material 102 may have a thickness equal to or less than the thickness of the gradient-doped control gate material 104 (e.g., the thickness of the isolation material 102 may be between 40% of the thickness of the gradient-doped control gate material 104 and 100% of the thickness of the gradient-doped control gate material 104).

The gradient-doped control gate material 104 may include a base material (e.g., polysilicon) and a dopant material (e.g., phosphorous). The concentration of the dopant in the base material may be non-uniform across the thickness of the gradient-doped control gate material 104 (i.e., in the “vertical” direction with reference to FIG. 1A). In some embodiments, the concentration of the dopant in the base material may be greatest proximate to the center of the base material along the axis of the isolation material 102/gradient-doped control gate material 104 stack. FIGS. 1B and 10 are example doping profiles that may be used in a gradient-doped control gate material 104, in accordance with various embodiments. In the embodiment of FIG. 1B, the concentration of the dopant in the base material is greatest proximate to the center of the base material along the axis of the isolation material 102/gradient-doped control gate material 104 stack, and may monotonically decrease towards the adjacent isolation material 102. In the embodiment of FIG. 10, the concentration of the dopant in the base material is greatest proximate to the center of the base material along the axis of the isolation material 102/gradient-doped control gate material 104 stack, and may not monotonically decrease towards the adjacent isolation material 102, but may include one or more additional local concentration “peaks”. Such additional peaks may be the result of migration of the dopant (e.g., due to annealing) into the gradient-doped control gate material 104 after the gradient-doped control gate material 104 is initially formed, so the dopant concentration peak proximate to the center of the base material along the axis of the isolation material 102/gradient-doped control gate material 104 stack may not be the only local peak in the doping profile. In other embodiments, the concentration of the dopant in the base material may be least proximate to the center of the base material along the axis of the isolation material 102/gradient-doped control gate material 104 stack (e.g., the doping profile may be a “flipped” version of the doping profiles of FIGS. 1B and 10). In some embodiments, the concentration of the dopant in the base material may have another non-uniform profile along the axis of the isolation material 102/gradient-doped control gate material 104 stack. For example, the concentration of the dopant in the base material of a portion of gradient-doped control gate material 104 may “ramp up” or “ramp down” from the “lower” isolation material 102 to the “upper” isolation material 102. In another example, the concentration of the dopant in the base material of a portion of gradient-doped control gate material 104 may include a combination of any of these profiles, or any other suitable non-uniform profile.

Use of a gradient-doped control gate material 104 as discussed above may advantageously reduce the concavity of the side faces of the gradient-doped control gate material 104 relative to conventional approaches, resulting in side faces of the gradient-doped control gate material 104 that are “flatter” than previously achievable. As discussed below with reference to FIG. 2D, fabrication of the memory device 100 may include a recess etch step in which an initial isolation material 102/gradient-doped control gate material 104 stack having uniform width of the isolation material 102 and gradient-doped control gate material 104 is subjected to etch conditions to cause the gradient-doped control gate material 104 to be laterally etched, resulting in side faces of the gradient-doped control gate material 104 being recessed from side faces of the proximate isolation material 102. In some conventional memory devices, in which the control gate material is not gradient-doped, this lateral etch proceeds non-uniformly, with the control gate material closer to the isolation material being etched more slowly than the control gate material spaced farther from the isolation material. The result of such a non-uniform etch may be control gate material with side faces that are concave, with the control gate material being wider closer to the proximate isolation material. This extra width of the control gate material may result in an undesirable shape of the associated memory cell. For example, the extra width of the control gate material may result in a larger overall footprint of the associated memory cell than is desired, reducing the achievable memory density. The gradient-doped control gate material 104 disclosed herein may exhibit reduced concavity of the side faces of the gradient-doped control gate material 104 relative to some conventional control gate materials. In particular, the concentration of the dopant in the base material may be related to the rate of etch of the gradient-doped control gate material 104, with more highly doped base material being etched more slowly than base material having a lower dopant concentration. Consequently, increasing the dopant concentration proximate to the “vertical” center of the gradient-doped control gate material 104 may slow down the lateral etch of the gradient-doped control gate material 104 at the vertical center, achieving a more uniform recessing and desirably flat side faces of the gradient-doped control gate material 104.

The memory devices 100 disclosed herein may be manufactured using any suitable techniques. For example, FIGS. 2A-2G illustrate stages in an example process of manufacturing the memory device 100 of FIG. 1. Although the operations of the process of FIG. 2 may be illustrated with reference to particular embodiments of the memory devices 100 disclosed herein, the process may be used to form any suitable memory devices (e.g., the memory device 100 of FIG. 3, discussed below). Operations are illustrated once each and in a particular order in FIG. 2, but the operations may be reordered and/or repeated as desired (e.g., with different operations performed in parallel when manufacturing multiple memory devices simultaneously).

FIG. 2A illustrates an assembly including a stack of layers of isolation material 102 alternating with layers of gradient-doped control gate material 104. The stack of FIG. 2A may be manufactured by alternatingly forming the layers of isolation material 102 and the layers of gradient-doped control gate material 104. In some embodiments, a layer of gradient-doped control gate material 104 may be formed by adjusting the amount of dopant present during deposition of the base material of the gradient-doped control gate material 104. For example, in some embodiments, the amount of phosphine present during deposition of the polysilicon of a layer of gradient-doped control gate material 104 may be adjusted to increase the concentration of phosphorous closer to the vertical center of the layer of gradient-doped control gate material 104 (or to achieve another desired concentration profile). Any suitable techniques may be used to form a layer of gradient-doped control gate material 104 with a desired doping profile.

FIG. 2B illustrates an assembly subsequent to forming a patterning structure 106 on the material stack of FIG. 2A. The patterning structure 106 may include any desired combination of mask/cap materials. For example, in some embodiments, the patterning structure 106 may include a nitride cap on the topmost layer of isolation material 102, followed by carbon hardmask and/or anti-reflective coating layers.

FIG. 2C illustrates an assembly subsequent to patterning the patterning structure 106 of FIG. 2B and then etching that pattern into the underlying stack of isolation material 102/gradient-doped control gate material 104 to form pillar trenches 108 in the isolation material 102/gradient-doped control gate material 104. Any suitable patterning and etch techniques may be used (e.g. lithographic patterning and etch techniques).

FIG. 2D illustrates an assembly subsequent to performing a selective lateral etch on the assembly of FIG. 2C to recess the exposed gradient-doped control gate material 104 relative to the isolation material 102. As discussed above, the non-uniform doping profile of the gradient-doped control gate material 104 may selectively “speed up” and/or “slow down” the etch in various locations along the profile of the gradient-doped control gate material 104, resulting in a more uniform lateral etch (and thus “flatter” sidewalls of the gradient-doped control gate material 104) than previously achievable.

FIG. 2E illustrates an assembly subsequent to conformally depositing the dielectric material 110 in the pillar trenches 108 of the assembly of FIG. 2D, and then etching the dielectric material 110 to leave the dielectric material 110 in the recesses formed by the recessed gradient-doped control gate material 104, as shown.

FIG. 2F illustrates an assembly subsequent to conformally depositing a floating gate material 112 in the pillar trenches 108 of the assembly of FIG. 2E, and then etching the floating gate material 112 to leave the floating gate material 112 in the recesses formed by the recessed gradient-doped control gate material 104/dielectric material 110, as shown.

FIG. 2G illustrates an assembly subsequent to conformally depositing a tunnel dielectric material 114 in the pillar trenches 108 of the assembly of FIG. 2F, and then filling the remainder of the pillar trenches 108 with the cell pillar material 116. The assembly of FIG. 2G may take the form of the memory device 100 of FIG. 1.

As noted above, in some embodiments, the dielectric material 110 may not have a C-shaped cross-section. For example, FIG. 3 is a side, cross-section view of another memory device 100 including gradient-doped control gate material 104, in accordance with various embodiments. The embodiment of FIG. 3 may share many features with the embodiment of FIG. 1, but the dielectric material 110 may have a substantially rectangular cross-section instead of a C-shaped cross-section. This particular variant is simply an example, and any of the elements of the memory devices 100 disclosed herein may have different shapes than those illustrated, as appropriate.

The memory devices 100 disclosed herein may be included in any suitable electronic component. FIGS. 4-8 illustrate various examples of apparatuses that may include any of the memory devices 100 disclosed herein.

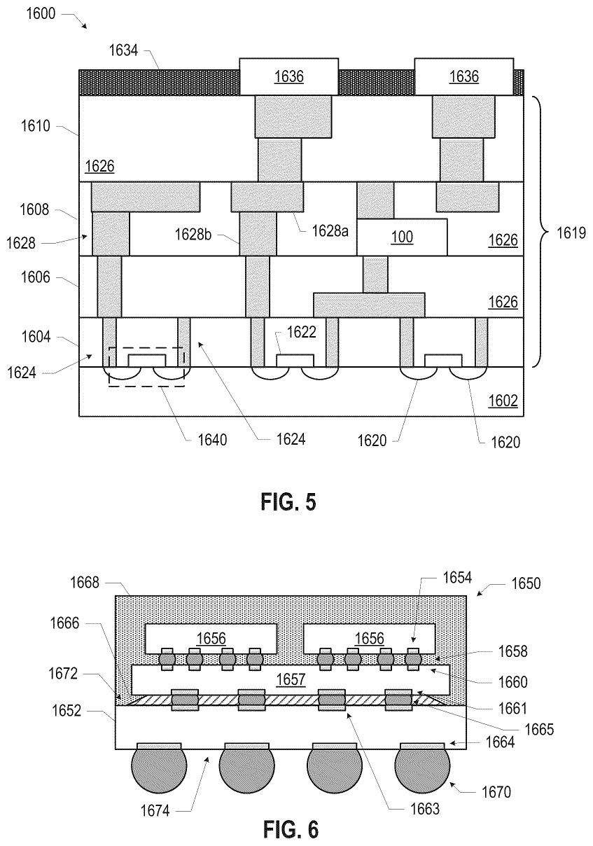

FIG. 4 is a top view of a wafer 1500 and dies 1502 that may include one or more memory devices 100 in accordance with any of the embodiments disclosed herein. The wafer 1500 may be composed of semiconductor material and may include one or more dies 1502 having integrated circuit (IC) structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more memory devices 100 (e.g., as discussed below with reference to FIG. 5), one or more transistors (e.g., some of the transistors 1640 of FIG. 5, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array.

FIG. 5 is a side, cross-sectional view of an IC device 1600 that may include one or more memory devices 100 in accordance with any of the embodiments disclosed herein. One or more of the IC devices 1600 may be included in one or more dies 1502 (FIG. 4). The IC device 1600 may be formed on a substrate 1602 (e.g., the wafer 1500 of FIG. 4) and may be included in a die (e.g., the die 1502 of FIG. 4). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 4) or a wafer (e.g., the wafer 1500 of FIG. 4).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 5 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 5 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600. In some embodiments, one or more memory devices 100 may be disposed in one or more of the interconnect layers 1606-1610, in accordance with any of the techniques disclosed herein. FIG. 5 illustrates a single memory device 100 in the interconnect layer 1608 for illustration purposes, but any number and structure of memory devices 100 may be included in any one or more of the layers in a metallization stack 1619. One or more memory devices 100 in the metallization stack 1619 may be coupled to any suitable ones of the devices in the device layer 1604, and/or to one or more of the conductive contacts 1636 (discussed below).

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 5). Although a particular number of interconnect layers 1606-1610 is depicted in FIG. 5, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 5. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 5. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 5, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 6 is a side, cross-sectional view of an example IC package 1650 that may include one or more memory devices 100 in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnect structures 1628 discussed above with reference to FIG. 5.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 6 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657.

The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 6 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

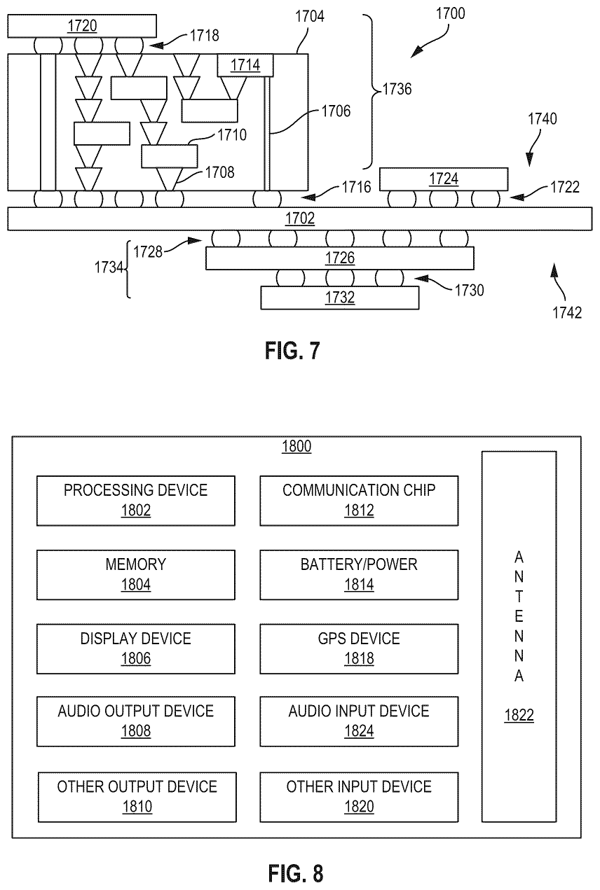

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 6 are solder balls (e.g., for a ball grid array arrangement), but any suitable second-level interconnects 16770 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 7.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory). In some embodiments, the die 1656 may include one or more memory devices 100 (e.g., as discussed above with reference to FIG. 4 and FIG. 5).

Although the IC package 1650 illustrated in FIG. 6 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 6, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 7 is a side, cross-sectional view of an IC device assembly 1700 that may include one or more IC packages or other electronic components (e.g., a die) including one or more memory devices 100, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 6 (e.g., may include one or more memory devices 100 in a die).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 4), an IC device (e.g., the IC device 1600 of FIG. 5), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 7, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more memory devices 100, in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is a memory device, including: a first isolation material; a second isolation material; and a control gate material between the first isolation material and the second isolation material along an axis, wherein the control gate material includes a dopant having a non-uniform concentration along the axis.

Example 2 includes the subject matter of Example 1, and further specifies that the control gate material includes polysilicon.

Example 3 includes the subject matter of any of Examples 1-2, and further specifies that the dopant includes phosphorous.

Example 4 includes the subject matter of any of Examples 1-3, and further specifies that the first isolation material and the second isolation material have a same material composition.

Example 5 includes the subject matter of any of Examples 1-4, and further specifies that the first isolation material includes oxygen.

Example 6 includes the subject matter of any of Examples 1-5, and further specifies that: the first isolation material has a first width in a direction perpendicular to the axis; the second isolation material has a second width in the direction perpendicular to the axis; the control gate material has a third width in the direction perpendicular to the axis; the third width is less than the first width; and the third width is less than the second width.

Example 7 includes the subject matter of Example 6, and further specifies that the first width is the same as the second width.

Example 8 includes the subject matter of any of Examples 1-7, and further includes: a dielectric material between the first isolation material and the second isolation material along the axis, wherein the dielectric material has a material composition that is different from a material composition of the first isolation material.

Example 9 includes the subject matter of Example 8, and further specifies that the dielectric material has a C-shaped cross-section.

Example 10 includes the subject matter of any of Examples 8-9, and further includes: a floating gate material between the first isolation material and the second isolation material along the axis, wherein the dielectric material is between the floating gate material and the control gate material.

Example 11 includes the subject matter of Example 10, and further specifies that the floating gate material includes polysilicon.

Example 12 includes the subject matter of any of Examples 1-11, and further includes: a tunnel dielectric material proximate to a face of the first isolation material and a face of the second isolation material.

Example 13 includes the subject matter of Example 12, and further specifies that the tunnel dielectric material includes oxygen or nitrogen.

Example 14 includes the subject matter of any of Examples 12-13, and further includes: a cell pillar material, wherein the tunnel dielectric material is between the cell pillar material and the first isolation material, and the tunnel dielectric material is between the cell pillar material and the second isolation material.

Example 15 includes the subject matter of Example 14, and further specifies that the cell pillar material includes polysilicon or silicon oxide.

Example 16 includes the subject matter of any of Examples 1-15, and further specifies that the dopant has a concentration that is greatest at a location proximate to a center of the control gate material along the axis.

Example 17 includes the subject matter of Example 16, and further specifies that the concentration of the dopant decreases from the location towards the first isolation material.

Example 18 includes the subject matter of any of Examples 16-17, and further specifies that the concentration of the dopant decreases from the location towards the second isolation material.

Example 19 includes the subject matter of any of Examples 1-15, and further specifies that the dopant has a concentration that is least at a location proximate to a center of the control gate material along the axis.

Example 20 includes the subject matter of Example 19, and further specifies that the concentration of the dopant increases from the location towards the first isolation material.

Example 21 includes the subject matter of any of Examples 19-20, and further specifies that the concentration of the dopant increases from the location towards the second isolation material.

Example 22 includes the subject matter of any of Examples 1-15, and further specifies that the dopant has a concentration that increases from the first isolation material towards the second isolation material.

Example 23 includes the subject matter of any of Examples 1-15, and further specifies that the dopant has a concentration that decreases from the first isolation material towards the second isolation material.

Example 24 is a memory device, including: an isolation material; and a control gate material in contact with the isolation material, wherein the control gate material is recessed relative to the isolation material in a first direction, the control gate material includes a dopant having a non-uniform concentration in a second direction perpendicular to the first direction.

Example 25 includes the subject matter of Example 24, and further specifies that the control gate material includes polysilicon.

Example 26 includes the subject matter of any of Examples 24-25, and further specifies that the dopant includes phosphorous.

Example 27 includes the subject matter of any of Examples 24-26, and further specifies that the isolation material includes oxygen.

Example 28 includes the subject matter of any of Examples 24-27, and further includes: a dielectric material in contact with the isolation material and in contact with the control gate material, wherein the dielectric material has a material composition that is different from a material composition of the isolation material.

Example 29 includes the subject matter of Example 28, and further specifies that the dielectric material has a C-shaped cross-section.

Example 30 includes the subject matter of any of Examples 28-29, and further includes: a floating gate material, wherein the dielectric material is between the floating gate material and the control gate material.

Example 31 includes the subject matter of Example 30, and further specifies that the floating gate material includes polysilicon.

Example 32 includes the subject matter of any of Examples 24-31, and further includes: a tunnel dielectric material proximate to a face of the isolation material.

Example 33 includes the subject matter of Example 32, and further specifies that the tunnel dielectric material includes oxygen or nitrogen.

Example 34 includes the subject matter of any of Examples 32-33, and further includes: a cell pillar material, wherein the tunnel dielectric material is between the cell pillar material and the isolation material.

Example 35 includes the subject matter of Example 34, and further specifies that the cell pillar material includes polysilicon.

Example 36 includes the subject matter of Example 34, and further specifies that the cell pillar material includes silicon oxide.

Example 37 includes the subject matter of any of Examples 24-36, and further specifies that the dopant has a concentration that is greatest at a location proximate to a center of the control gate material in the second direction.

Example 38 includes the subject matter of Example 37, and further specifies that the concentration of the dopant decreases from the location towards the isolation material.

Example 39 includes the subject matter of any of Examples 24-36, and further specifies that the dopant has a concentration that is least at a location proximate to a center of the control gate material in the second direction.

Example 40 includes the subject matter of Example 39, and further specifies that the concentration of the dopant increases from the location towards the isolation material.

Example 41 includes the subject matter of any of Examples 24-36, and further specifies that the dopant has a concentration that increases towards the isolation material.

Example 42 includes the subject matter of any of Examples 24-36, and further specifies that the dopant has a concentration that decreases towards the isolation material.

Example 43 is a memory device, including: an oxide-polysilicon-oxide stack having a polysilicon layer between two oxide layers, wherein the polysilicon layer is recessed relative to the oxide layers; wherein the polysilicon layer has a non-uniform concentration of phosphorous therein.

Example 44 includes the subject matter of Example 43, and further specifies that the polysilicon layer has a phosphorous concentration that is greatest proximate to a location in the polysilicon layer equidistant from the oxide layers.

Example 45 includes the subject matter of any of Examples 43-44, and further includes: a dielectric material between the oxide layers, wherein the dielectric material has a material composition that is different from a material composition of the oxide layers.

Example 46 includes the subject matter of Example 45, and further specifies that the dielectric material has a C-shaped cross-section.

Example 47 includes the subject matter of any of Examples 45-46, and further includes: a polysilicon region between the oxide layers, wherein the dielectric material is between the polysilicon layer and the polysilicon region.

Example 48 includes the subject matter of any of Examples 43-47, and further includes: a tunnel dielectric material proximate to side faces of the oxide layers.

Example 49 includes the subject matter of Example 48, and further specifies that the tunnel dielectric material includes oxygen or nitrogen.

Example 50 includes the subject matter of any of Examples 48-49, and further includes: a cell pillar material, wherein the tunnel dielectric material is between the cell pillar material and the oxide layers.

Example 51 includes the subject matter of Example 50, and further specifies that the cell pillar material includes polysilicon or silicon oxide.

Example 52 is an integrated circuit (IC) assembly, including: an IC die including the memory device of any of Examples 1-51; and a package substrate coupled to the IC die.

Example 53 includes the subject matter of Example 52, and further includes: a circuit board, wherein the package substrate is coupled to the circuit board.

Example 54 includes the subject matter of Example 53, and further specifies that the circuit board is a motherboard.

Example 55 includes the subject matter of any of Examples 52-54, and further includes: a display.

Example 56 includes the subject matter of any of Examples 52-55, and further includes: an antenna.

Example 57 includes the subject matter of any of Examples 52-56, and further specifies that the IC assembly is a server computing device.

Example 58 includes the subject matter of any of Examples 52-56, and further specifies that the IC assembly is a handheld computing device.

1. A memory device, comprising:
a first isolation material;
a second isolation material; and
a control gate material between the first isolation material and the second isolation material along an axis, wherein the control gate material includes a dopant having a non-uniform concentration along the axis.

2. The memory device of claim 1, wherein the control gate material includes polysilicon.

3. The memory device of claim 1, wherein the dopant includes phosphorous.

4. The memory device of claim 1, wherein the first isolation material includes oxygen.

5. The memory device of claim 1, wherein the dopant has a concentration that is greatest at a location proximate to a center of the control gate material along the axis.

6. The memory device of claim 1, wherein the dopant has a concentration that is least at a location proximate to a center of the control gate material along the axis.

7. The memory device of claim 1, wherein the dopant has a concentration that increases from the first isolation material towards the second isolation material.

8. A memory device, comprising:
an isolation material; and
a control gate material in contact with the isolation material, wherein the control gate material is recessed relative to the isolation material in a first direction, the control gate material includes a dopant having a non-uniform concentration in a second direction perpendicular to the first direction.

9. The memory device of claim 8, further comprising:
a dielectric material in contact with the isolation material and in contact with the control gate material, wherein the dielectric material has a material composition that is different from a material composition of the isolation material.

10. The memory device of claim 9, further comprising:
a floating gate material, wherein the dielectric material is between the floating gate material and the control gate material.

11. The memory device of claim 8, further comprising:
a tunnel dielectric material proximate to a face of the isolation material.

12. The memory device of claim 11, further comprising:
a cell pillar material, wherein the tunnel dielectric material is between the cell pillar material and the isolation material.

13. The memory device of claim 8, wherein the dopant has a concentration that increases towards the isolation material.

14. The memory device of claim 8, wherein the dopant has a concentration that decreases towards the isolation material.

15. A memory device, comprising:
an oxide-polysilicon-oxide stack having a polysilicon layer between two oxide layers, wherein the polysilicon layer is recessed relative to the oxide layers;
wherein the polysilicon layer has a non-uniform concentration of phosphorous therein.

16. The memory device of claim 15, wherein the polysilicon layer has a phosphorous concentration that is greatest proximate to a location in the polysilicon layer equidistant from the oxide layers.

17. The memory device of claim 15, further comprising:
a dielectric material between the oxide layers, wherein the dielectric material has a material composition that is different from a material composition of the oxide layers.

18. The memory device of claim 17, wherein the dielectric material has a C-shaped cross-section.

19. The memory device of claim 17, further comprising:
a polysilicon region between the oxide layers, wherein the dielectric material is between the polysilicon layer and the polysilicon region.

20. The memory device of claim 15, further comprising:
a tunnel dielectric material proximate to side faces of the oxide layers.
